(19) United States
(12) Patent Application Publication
(10) Pub. No.: US 2012/0145441 A1
(43) Pub. Date: Jun. 14, 2012

(54) Dielectric layer of printed circuit board, method for preparing the same, and printed circuit board including the same

(75) Inventors: Pochul Kim, Anyang-si (KR); Dongjin Kim, Gwangmyeong-si (KR); Sangik Cho, Suwon-si (KR); Woojin Lee, Daejeon-si (KR); Sooyoung Ji, Daejeon-si (KR)

(73) Assignee: SAMSUNG ELECTRO-MECHANICS CO., LTD, Suwon (KR)

(21) Appl. No.: 13/067,533

(22) Filed: Jun. 7, 2011

(30) Foreign Application Priority Data
Dec. 14, 2010 (KR) 10-2010-0127343

(51) Int. Cl. H05K 1/02; H05K 3/00

(52) U.S. Cl. 174/258; 427/96.1

(57) ABSTRACT

Disclosed herein are a dielectric layer of a printed circuit board prepared by dispersing short fibers in a dielectric polymer resin; and impregnating the resin having the short fibers dispersed therein in a fabric-shaped material, and a printed circuit board including the same. The dielectric polymer resin is reinforced with the short fibers and is impregnated in the fabric-shaped material, thereby making it possible to prepare the dielectric layer having excellent strength and low coefficient of thermal expansion. Accordingly, the printed circuit board including the dielectric layer may maintain strength and rigidity thereof at the same level as that of strength and rigidity of the printed circuit board according to the related art, even through a thickness thereof becomes thin.

### CROSS REFERENCE(S) TO RELATED APPLICATIONS

This application claims the benefit under 35 U.S.C. Section 119 of Korean Patent Application Serial No. 10-2010-0127343, entitled “Dielectric Layer of Printed Circuit Board, Method for Preparing the Same, and Printed Circuit Board Including the Same” filed on Dec. 14, 2010, which is hereby incorporated by reference in its entirety into this application.

### BACKGROUND OF THE INVENTION

1. Technical Field

The present invention relates to a dielectric layer of a printed circuit board, a method for preparing the same, and a printed circuit board including the same.

2. Description of the Related Art

Companies producing electronic products such as a portable phone represented by a smart phone; and a television represented by a plasma display panel (PDP), a liquid crystal display (LCD), a light emitting diode, and the like, have contended with respect to minimization of a thickness thereof as well as most excellent performance thereof. In addition, as a level of customers becomes high, many competitive products for slimness of the electronic product such as the portable phone or the television have been continuously launched.

These electronic products have a large number of electronic components mounted on a printed circuit board (PCB). Accordingly, various efforts have been conducted in order to reduce thicknesses of the electronic products; however, it is more effective to reduce a thickness of the PCB than reducing the thicknesses of the large number of electronic components included in the electronic components. Therefore, the demand for developing a slim PCB has increased.

In the case in which the thickness of the PCB is reduced, problems occur in that the PCB is warped due to mounting force when the electronic components are mounted on the PCB in addition to the PCB being warped due to heat generated in a reflow process. In addition, in the case in which the thickness of the PCB is reduced, the PCB is easily broken due to external load such as impact. Owing to these problems, strength of the PCB itself should be increased.

However, owing to a trade-off problem that the PCB is warped as the thickness of the PCB becomes thin, it is necessary to increase the strength of the PCB in order to minimize the warp problem.

Generally, the PCB is extended or shortened in a thickness direction thereof due to heat generated in a reflow process, heat generated during use of the electronic product, or heat from a surrounding environment. The PCB configured of several layers is subject to a ‘plated through hole (PTH)’ process of boring a hole in the PCB for conductive connection between an inner layer and an outer layer and plating the hole with a metal. However, when the extended or shortened amount of the PCB is large, the metal plated to the PHT is broken at one time, and although the extended or shortened amount of the PCB is small, when the extension or the shortening is repeatedly generated, the metal plated to the PHT is broken due to fatigue failure. Accordingly, in order to prevent this phenomenon, deformation amount of the PCB in a thickness direction thereof due to the heat should be minimized by lowering coefficient of thermal expansion (CTE) of the PCB in the thickness direction thereof.

The PCB is configured of copper layers forming a circuit, and a dielectric layer for insulation between the copper layers. Since the copper layer of the components of the PCB should form the circuit, it is impossible to change the material of the copper layer. Therefore, the material of the dielectric layer cannot but be changed in order to increase rigidity and strength of PCB reduce the CTE.

The dielectric layer of the PCB has been made of only a dielectric polymer resin or a composite material including the dielectric polymer material. However, the dielectric layer made of only the dielectric polymer resin has a limitation in being used for a slim PCB due to low rigidity, low strength, and high CTE. In addition, in the dielectric layer made of the composite material, there was a need to further increase the strength and the rigidity of the dielectric layer and further reduce the CTE in order to accomplish the slimness of the PCB.

### SUMMARY OF THE INVENTION

An object of the present invention is to provide a dielectric layer of a printed circuit board minimizing coefficient of thermal expansion (CTE), while maximally increasing strength and rigidity for slimness of the printed circuit board.

Another object of the present invention is to provide a method for preparing a dielectric layer of a printed circuit board having the above-mentioned characteristics.

Another object of the present invention is to provide a printed circuit board including the dielectric layer.

According to an exemplary embodiment of the present invention, there is provided a dielectric layer of a printed circuit board, including: a dielectric polymer resin; short fibers; and a fabric-shaped material.

The dielectric polymer resin may be at least one selected from a group consisting of a thermosetting resin, a thermoplastic resin, and a mixed resin thereof.

The thermosetting resin may be at least one selected from a group consisting of an epoxy resin, a phenol resin, an epoxy acrylate resin, a melamine resin, a polyphenyleneether resin, a polyethersulphone resin, a polyetheretherketone resin, a polyphenylenesulphide resin, a polyphenyleneether resin, a polyphenyleneoxide resin, a polyimide resin, a polyamideimide resin, a polyetherimide resin, a polysulphone resin, a polyketone resin, a polyetherketone resin, resin, a fluororesin, a polyurethane based resin, a polyisoprene resin, a copolymer thereof, a modified resin thereof, and a mixture thereof.

The thermoplastic resin may be at least one selected from a group consisting of a polyethylene terephthalate (PET) resin, a polybuthylene terephthalate (PBT) resin, a polytrimethylene terephthalate resin, a polyethylene naphthalate resin, a polyethylene resin, a polypropylene resin, a styrene based resin, a polyoxymethylene resin, a polyamide resin, a polycarbonate resin, a polymethylemethacrylate resin, a polyvinylchloride resin, a copolymer thereof, a modified resin thereof, and a mixture thereof.

The short fiber may have a length in a range of 0.5 to 5 mm.

The short fiber may be at least one selected from a group consisting of a glass fiber and an aramid fiber.

The fabric-shaped material may be at least one selected from a group consisting of a glass fabric, a non-woven, a fibrous material.

According to another exemplary embodiment of the present invention, there is provided a method for preparing a dielectric layer of a printed circuit board, including: dispersing short fibers in a dielectric polymer resin; and impregnating the resin having the short fibers dispersed therein in a fabric-shaped material.

The short fibers may be dispersed to have content within 20 parts by weight with respect to 100 parts by weight of the dielectric polymer resin.

The dielectric polymer resin may be used in a melted state.

The resin having the short fibers dispersed therein may be dispersed between respective raw materials configuring the fabric-shaped material during the impregnation of the resin in the fabric-shaped material.

After the resin having the short fibers dispersed therein is dispersed in the fabric-shaped material, a shape of the short fibers may be maintained, as it is.

According to another exemplary embodiment of the present invention, there is provided a printed circuit board including a dielectric layer including a dielectric polymer resin, short fibers, and a fabric-shaped material.

### BRIEF DESCRIPTION OF THE DRAWINGS

FIGS. 1 and 2 are views showing a process for preparing a dielectric layer and a structure thereof according to an exemplary embodiment of the present invention;

FIGS. 3 to 5 are views showing tensile strength results of the dielectric layer according to Comparative Example 1 and Example 1; and

FIGS. 6 and 7 are views showing coefficient of thermal expansion measurement results of the dielectric layer according to Comparative Example 1 and Example 1.

### DESCRIPTION OF THE PREFERRED EMBODIMENTS

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, preferred embodiments of the present invention will be described in detail with reference to the accompanying drawings.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

In addition, a thickness or a size of each layer will be exaggerated for convenience of explanation or clarity and like reference numbers will indicate the same components, in the drawings below. As used in the present specification, a term “and/or” includes any one or at least one combination of enumerated items.

In the present specification, although terms such as a first, a second, etc., are used to explain various members, components, areas, layers and/or portions thereof, these members, components, areas, layers and/or portions thereof are not limited to these terms. These terms are used only to distinguish one member, component, area, layer or a portion thereof from another member, component, area, layer or a portion thereof. Accordingly, a first member, a first component, a first area, a first layer, or a portion thereof described below may indicate a second member, a second component, a second area, a second layer, or a portion thereof.

The present invention relates to a dielectric layer increasing strength and rigidity of a printed circuit board and minimizing coefficient of thermal expansion. The dielectric layer is made of a dielectric polymer resin, short fibers, and a fabric-shaped material.

The dielectric polymer resin included in the dielectric layer according to an exemplary embodiment of the present invention is a material having insulating characteristics. The dielectric polymer resin may be at least one selected from a group consisting of a thermosetting resin, a thermoplastic resin, and a mixed resin thereof, without being particularly limited thereto.

The thermosetting resin may be at least one selected from a group consisting of an epoxy resin, a phenol resin, an epoxy acrylate resin, a melamine resin, a polyphenyleneether resin, a polyethersulphone resin, a polyetheretherketone resin, a polyphenylenesulphide resin, a polyphenyleneether resin, a polyphenyleneoxide resin, a polyimide resin, a polyamideimide resin, a polyetherimide resin, a polysulphone resin, a polyketone resin, a polyetherketone resin, a fluororesin, a polyurethane based resin, a polyisoprene resin, a copolymer thereof, a modified resin thereof, and a mixture thereof, without being particularly limited thereto.

In addition, the thermoplastic resin may be at least one selected from a group consisting of a polyethylene terephthalate (PET) resin, a polybuthylene terephthalate (PBT) resin, a polytrimethylene terephthalate resin, a polyethylene naphthalate resin, a polyethylene resin, a polypropylene resin, a styrene based resin, a polyoxymethylene resin, a polyamide resin, a polycarbonate resin, a polymethylemethacrylate resin, a polyvinylchloride resin, a copolymer thereof, a modified resin thereof, and a mixture thereof, without being particularly limited thereto.

A mixed resin formed by mixing the thermosetting resin and the thermoplastic resin may be used. Among the enumerated resins, the epoxy resin may be most preferably used in consideration of insulation characteristics, and the like, without being also limited thereto.

In addition, the dielectric layer disperses the short fibers having a short length in the dielectric polymer resin. In this case, the short fiber has preferably a length in a range of 0.5 to 5 mm.

When the length of the short fiber is below 0.5 mm, a slenderness ratio is small to reduce mechanical property improvement effect, and when the length of the short fiber exceeds 0.5 mm, which is excessively long, it is difficult to mix the short fibers with the dielectric polymer resin when the short fibers are dispersed in the dielectric polymer resin to cause non-uniform distribution of the fiber, thereby not satisfactorily accomplishing a reinforcing effect.

According to an exemplary embodiment of the present invention, the short fibers may be at least one selected from a group consisting of a glass fiber and an aramid fiber.

The glass fiber according to an exemplary embodiment of the present invention is made of at least one selected from a group consisting of E glass, silica glass, D glass, S glass, T glass, C glass, and H glass; however, a method for preparing the glass fiber is not particularly limited thereto. The glass fiber may be directly prepared, or a glass fiber on sale may be used.

In addition, as the aramid fiber, products known as product names such as ‘Kevlar’ available from DuPont, Co., U.S.A, ‘TWARON’ available from Teijin Pharma, Ltd., Japan, ‘Heraclon’ available from Kolon, Ltd., Korea, may be used.

The aramid fiber having five times higher strength than that of steel having the same weight is the strongest fiber among existing fibers, and is a high performance material having excellent heat resistance that does not burn even at 500° C. and strong chemical resistance. In addition, the aramid fiber is lighter, is less worn, and is more conveniently processed, as compared to a metal or an inorganic material. Accordingly, the aramid fiber has been used in various industrial fields such as a high performance tire, a hose, a belt, an optical cable reinforcement material, a bulletproof vest, a bulletproof helmet, a break friction material, a gasket sealing material, and the like.

In addition, according to an exemplary embodiment of the present invention, the fabric-shaped material may be at least one selected from a group consisting of a glass fabric, a non-woven, a fibrous material, and is not particularly limited if it has a fabric shape.

For example, the fabric-shaped material is not particularly limited if it is a cloth or a fabric that becomes a plane body having a predetermined area by weaving warps and wefts to be vertically intersected with each other; or a nonwoven-shaped cloth prepared by mechanically treating the fibers to be tangled with each other using heat and resin; or a glass fabric; or other various fibrous materials.

In addition, all the fabric-shaped materials may be used if they may impregnate the dielectric polymer resin in which the short fibers are dispersed therein.

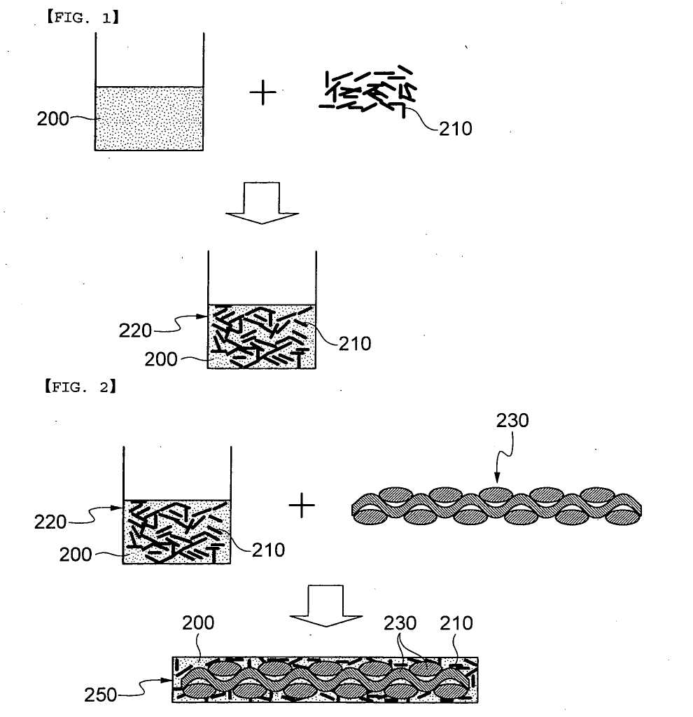

Hereinafter, a method for preparing a dielectric layer of a printed circuit board according to an exemplary embodiment of the present invention will be described in detail with reference to accompanying drawings. The method for preparing a dielectric layer of a printed circuit board according to an exemplary embodiment of the present invention may includes dispersing short fibers 210 in a dielectric polymer resin 200 to finally prepare a resin 220 having the short fibers dispersed therein, as shown in FIG. 1; and impregnating the resin 220 having the short fibers dispersed therein in a fabric-shaped material 230 to the short fiber reinforcing dielectric layer 250, as shown in FIG. 2.

First, the short fibers 210 are dispersed in the dielectric polymer resin 200. In this case, the dielectric polymer resin exists, preferably, in a liquid phase for dispersion of the short fibers, as shown in FIG. 1. For example, the dielectric polymer resin is used in a melted state or the dielectric polymer resin itself is, preferably, a liquid phase.

In the case in which the short fibers 210 are dispersed in the dielectric polymer resin 200 as described above, the resin 220 in which the short fibers are uniformly dispersed in dielectric polymer resin solution may be obtained, as shown in FIG. 1.

When the short fibers are dispersed in the dielectric polymer resin, it may be dispersed to have content within 20 parts by weight, preferably, in a range of 0.01 to 10 parts by weight with respect to 100 parts by weight of the dielectric polymer resin. When the content of the short fiber exceeds 20 parts by weight, a problem is generated in the dispersion.

Then, the resin 220 having the short fibers 210 dispersed therein is impregnated in the fabric-shaped material 230. The fabric-shaped material 230 used in this case is not particularly limited if it has a fabric shape so that the resin 220 having the short fibers dispersed therein may be impregnated therein. For example, the fabric-shaped material 230 may be a woven fibrous material, a fibrous material prepared by applying mechanical force thereto such as a nonwoven, a glassy fabric, or the like. Among them, the glassy fabric is most preferable, without being limited thereto.

According to an exemplary embodiment of the present invention, the resin 220 having the short fibers 210 dispersed therein may be dispersed between respective raw materials configuring the fabric-shaped material 230 during the impregnation of the resin 220 in the fabric-shaped material 230, as shown in FIG. 2. For example, in the case in which the fabric-shaped material is a fibrous material having warps and wefts woven with each other, when the resin having the short fibers dispersed therein is impregnated in the fabric-shaped material, the resin may also be impregnated between the warps and the wefts.

Accordingly, as shown in FIG. 2, although the resin having the short fibers dispersed therein is impregnated in the fabric-shaped material, a shape of the short fibers 210 may be maintained, as it is, in the finally obtained short fiber reinforcing dielectric layer 250. However, when the resin having the short fibers dispersed therein is impregnated in the fabric-shaped material, the dielectric polymer resin in a liquid phase has a solid shape, and has sufficient increased strength due to the short fibers.

A thickness of the short fiber reinforcing dielectric layer prepared according to an exemplary embodiment of the present invention is 0.1 mm or less, and the short fiber reinforcing dielectric layer may be used by being stacked as several layers or may be prepared by impregnating the resin having the short fibers dispersed therein in the fabric-shaped material as several layers.

The dielectric layer according to an exemplary embodiment of the present invention prepared through a process described above may increase the strength thereof by reinforcing the dielectric polymer resin with several short fibers and impregnating the dielectric polymer resin reinforced with the several short fibers in the fabric-shaped material.

In addition, the present invention provides a printed circuit board including the dielectric layer having the dielectric polymer resin, the short fibers, and the fabric-shaped material.

The printed circuit board according to an exemplary embodiment of the present invention includes the dielectric layer having reinforced strength, thereby making it possible to solve a problem that the strength thereof becomes weak according to slimness of the printed circuit board.

Hereinafter, the present invention will be described in detail with reference to Examples. Examples of the present invention are provided in order to more completely explain the present invention to those skilled in the art. Examples below may be modified in several different forms and does not limit a scope of the present invention. Rather, these Examples are provided in order to make this disclosure more thorough and complete and completely transfer ideas of the present invention to those skilled in the art.

### EXAMPLE 1

10 parts by weight of glass short fibers (2 mm) were dispersed with respect to 100 parts by weight of epoxy dielectric polymer resin in a liquid phase to prepare a resin having the glass short fibers dispersed therein.

The resin having the glass short fibers dispersed therein was impregnated in a glass fabric to prepare short fiber reinforcing dielectric layer made of the glass fabric, the dielectric polymer resin, and the glass short fibers.

### COMPARATIVE EXAMPLE 1

A dielectric layer made of a glass fabric and an epoxy dielectric polymer resin was prepared and was used as Comparative Example.

### EXPERIMENTAL EXAMPLE

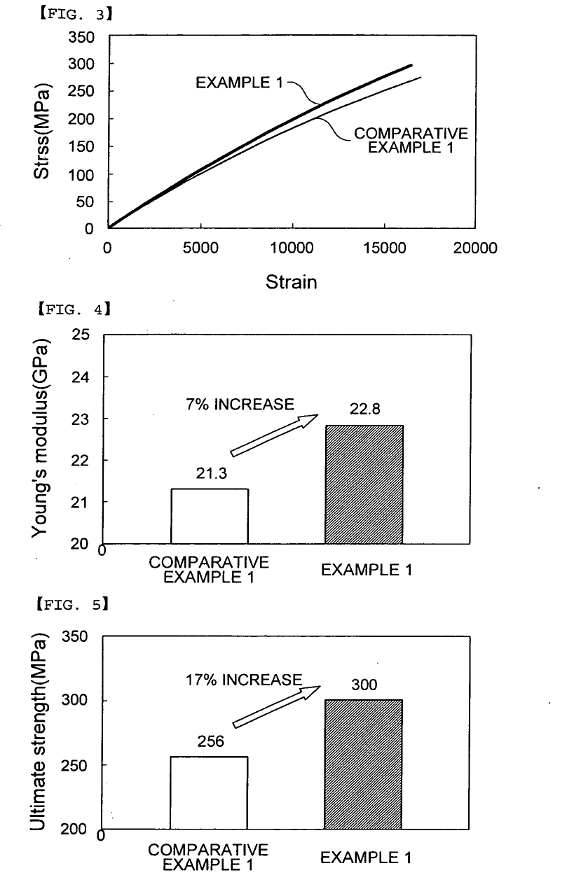

Tensile strength and coefficient of thermal expansion of dielectric layers prepared according to Example 1 and Comparative Example 1 were measured as follows. The measurement results were shown in FIGS. 3 to 7.

1) Tensile strength: Each dielectric layer specimen was cut in a dumbbell shape and tensile strength thereon was measure using a tensile tester available from Instron, Co. FIG. 3 is a view showing a measurement result of stresses acting on each specimen when each specimen is strained.

In addition, Young's modulus of FIG. 4, which is a value obtained by dividing the stress by the strain was used as a standard indicating a degree of rigidity.

Further, ultimate strength of FIG. 5 indicates strength of each specimen when each specimen is maximally strained.

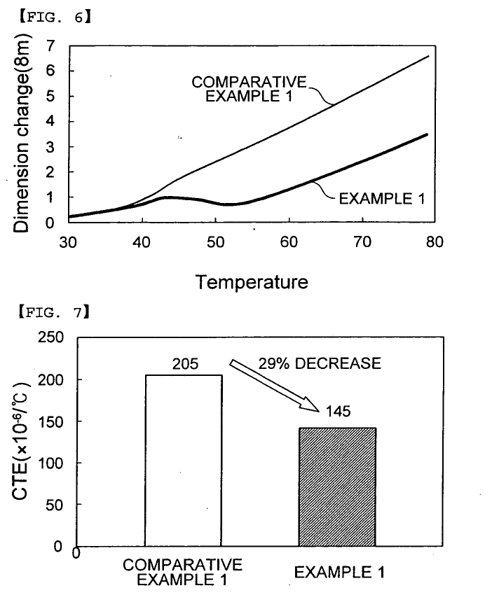

2) Coefficient of thermal expansion: A change in dimension according to a change in temperature with respect to each obtained dielectric layer specimen was measured using TMA. The measurement result was shown in FIG. 6. FIG. 7 is a view showing a comparison result of coefficients of thermal expansion of each specimen.

As seen in FIGS. 3 to 5, the dielectric layer (Example 1) prepared by dispersing the short fibers in the dielectric polymer resin to obtain the dielectric polymer resin having the short fibers dispersed therein and impregnating the dielectric polymer resin in the fabric-shaped material according to an exemplary embodiment of the present invention were more excellent in terms of both of rigidity and strength, as compared to the dielectric layer (Comparative Example 1) made of only the dielectric polymer resin and the glass fabric according to the related art, as a result of the tensile strength test.

In addition, as seen in TMA measure results of FIGS. 6 and 7, the coefficient of thermal expansion according to Example 1 has been reduced by 29%, as compared to Comparative Example 1.

Accordingly, when the dielectric layer according to an exemplary embodiment of the present invention is included in the printed circuit board, the dielectric layer is reinforced with the short fibers to improve properties such as strength, rigidity, and the like, of the printed circuit board and although the printed circuit board is subject to a ‘plated through hole (PTH)’ process, and the like, the coefficient of thermal expansion (CTE) of the PCB in a thickness direction thereof is lowered, thereby making it possible to solve a problem such as breakage or deformation of the PCB due to heat.

According to the exemplary embodiment of the present invention, it is possible to prepare the dielectric layer having excellent strength and low coefficient of thermal expansion by reinforcing the dielectric polymer resin with short fibers and impregnating the dielectric polymer resin reinforced with the short fibers in a fabric-shaped material.

In addition, the printed circuit board including the dielectric layer may maintain strength and rigidity thereof at the same level as that of strength and rigidity of the printed circuit board according to the related art, even through a thickness thereof becomes thin. Although the PCB is subject to a process of boring a hole therein, the PCB has low coefficient for thermal expansion, such that deformation such as breakage of the metal plated to the PCB, or the like, may be minimized.

Although the exemplary embodiments of the present invention have been shown and described, the present invention is not limited thereto but various changes and modifications may be made by those skilled in the art without departing from the spirit of the invention.

What is claimed is:

1. A dielectric layer of a printed circuit board, comprising:
a dielectric polymer resin;
short fibers; and
a fabric-shaped material.

2. The dielectric layer of a printed circuit board according to claim 1, wherein the dielectric polymer resin is at least one selected from a group consisting of a thermosetting resin, a thermoplastic resin, and a mixed resin thereof.

3. The dielectric layer of a printed circuit board according to claim 2, wherein the thermosetting resin is at least one selected from a group consisting of an epoxy resin, a phenol resin, an epoxy acrylate resin, a melamine resin, a polyphenyleneether resin, a polyethersulphone resin, a polyetheretherketone resin, a polyphenylenesulphide resin, a polyphenyleneether resin, a polyphenyleneoxide resin, a polyimide resin, a polyamideimide resin, a polyetherimide resin, a polysulphone resin, a polyketone resin, a polyetherketone resin, a fluororesin, a polyurethane based resin, a polyisoprene resin, a copolymer thereof, a modified resin thereof, and a mixture thereof.

4. The dielectric layer of a printed circuit board according to claim 2, wherein the thermoplastic resin is at least one selected from a group consisting of a polyethyleneterephthalate (PET) resin, a polybuthyleneterephthalate (PBT) resin, a polytrimethyleneterephthalate resin, a polyethylenenaphthalate resin, a polyethylene resin, a polypropylene resin, a styrene based resin, a polyoxymethylene resin, a polyamide resin, a polycarbonate resin, a polymethylemethacrylate resin, a polyvinylchloride resin, a copolymer thereof, a modified resin thereof, and a mixture thereof.

5. The dielectric layer of a printed circuit board according to claim 1, wherein the short fiber has a length in a range of 0.5 to 5 mm.

6. The dielectric layer of a printed circuit board according to claim 1, wherein the short fiber is at least one selected from a group consisting of a glass fiber and an aramid fiber.

7. The dielectric layer of a printed circuit board according to claim 1, wherein the fabric-shaped material is at least one selected from a group consisting of a glass fabric, a non-woven, a fibrous material.

8. A method for preparing a dielectric layer of a printed circuit board, comprising:
dispersing short fibers in a dielectric polymer resin; and
impregnating the resin having the short fibers dispersed therein in a fabric-shaped material.

9. The method for preparing a dielectric layer of a printed circuit board according to claim 8, wherein the short fibers are dispersed to have content within 20 parts by weight with respect to 100 parts by weight of the dielectric polymer resin.

10. The method for preparing a dielectric layer of a printed circuit board according to claim 8, wherein the dielectric polymer resin is used in a melted state.

11. The method for preparing a dielectric layer of a printed circuit board according to claim 8, wherein the resin having the short fibers dispersed therein is dispersed between respective raw materials configuring the fabric-shaped material during the impregnation of the resin in the fabric-shaped material.

12. The method for preparing a dielectric layer of a printed circuit board according to claim 8, wherein after the resin having the short fibers dispersed therein is dispersed in the fabric-shaped material, a shape of the short fibers is maintained, as it is.

13. A printed circuit board comprising a dielectric layer according to claim 1.
